(19) United States
(12) Patent Application Publication
(10) Pub. No.: US 2026/0119772 A1
(43) Pub. Date: Apr. 30, 2026

(54) Method for Transistor Order Placement Using Graph Neural Network Recursive Model

(71) Applicant: GenChip.AI Inc., Sunnyvale, CA (US)

(72) Inventors: Sreekar Bathula, San Jose, CA (US); Eric Panning, Portland, OR (US)

(21) Appl. No.: 19/376,746

(22) Filed: Oct. 31, 2025

Related U.S. Application Data
(60) Provisional application No. 63/714,793, filed on Oct. 31, 2024.
(60) Provisional application No. 63/714,754, filed on Oct. 31, 2024.
(60) Provisional application No. 63/714,761, filed on Oct. 31, 2024.
(60) Provisional application No. 63/714,797, filed on Oct. 31, 2024.
(60) Provisional application No. 63/714,796, filed on Oct. 31, 2024.
(60) Provisional application No. 63/714,773, filed on Oct. 31, 2024.

(51) Int. Cl. G06F 30/392; G06F 30/31; G06F 30/323; G06N 3/042; G06N 3/044; G06N 3/045; G06N 3/09

(52) U.S. Cl. CPC G06F 30/392; G06F 30/31; G06F 30/323; G06N 3/042; G06N 3/044; G06N 3/045; G06N 3/09

(57) ABSTRACT

A method for automating semiconductor design using a graph neural network (GNN) and transformer architecture. The method includes receiving a netlist of an integrated circuit from an electronic design automation tool, identifying transistors as nodes, and creating a GNN that connects these nodes. The method generates node embeddings for the GNN, orders the node embeddings, and performs parasitic extraction between nodes to generate parasitic extraction values. The method then generates a placement order of the transistors for physical layout based on specified design parameter values of performance and power and other metrics.

### CROSS-REFERENCE TO RELATED APPLICATIONS

This application claims the benefit of and priority to U.S. Provisional Patent Application Ser. No. 63/714,754 entitled “Method for Estimating Parasitic Capacitance Using Spatial Localization,” 63/714,761 entitled “Method and System for Estimating Parasitic Capacitance Using Localized Weighting and Federated Learning Model,” 63/714,793 entitled “Method for Transistor Order Placement Using Graph Neural Network Recursive Model,” 63/714,797 entitled “Method for Transistor Layout Generation Using Graph Neural Network Recursive Model,” 63/714,796 entitled “Method for Transistor Layout Design Checking Using Reinforcement Learning,” and 63/714,773 entitled “Method For Transistor Layout Design Using 3D Model Representation in Latent Space,” all of which were filed on Oct. 31, 2024 and which applications are expressly incorporated herein by reference in their entirety.

### BACKGROUND OF THE INVENTION

The present disclosure generally relates to electronic design automation for the design and manufacture of integrated circuits and microelectronics.

Electronic design automation (EDA) includes software tools for designing electronic systems such as integrated circuits. With semiconductor chips having billions of components or more, computer-aided tools are essential for logical design, physical design, and manufacturing processes. Integrated circuit design includes many steps, typically beginning with a system specification. After system specification, several logical design steps can be completed based on that specification including register transfer level design, functional verification, timing simulation, and netlist generation. After logical design, physical design steps can be executed to generate a physical layout of the integrated circuit. There are many physical design steps including partitioning, floor planning, placement, clock tree synthesis, and signal routing, among others. After a physical layout is verified, then an integrated circuit can be fabricated using the physical layout generated from EDA tools.

EDA tools are helpful to optimize the production process for semiconductor devices, such as integrated circuits. Such optimization involves designing semiconductor layouts and evaluating properties of the designs. Important properties assessed include resistance and capacitance, which are instrumental in deriving estimates for Power, Performance, Area, and Cost (PPAC) of a semiconductor device. The accurate estimation of these properties can significantly influence cost savings. Various tools are employed in this process to perform detailed 3D assessments of the designs, enabling precise point-to-point calculations of resistance and capacitance. During the physical design process of an integrated circuit, a significant variable to generating an acceptable design that meets logical constraints and system specifications is parasitic capacitance. Parasitic capacitance is the unwanted, yet unavoidable, capacitance that exists between conductive parts of an electronic circuit. Parasitic capacitance can cause the behavior of chip components to depart from ideal performance. The calculation of resistance and capacitance thus plays an important role in determining power and performance values.

Physical layout design for integrated circuits is often complicated, challenging, and time consuming. A given logical design can identify the logical circuits and transistors to be included in a particular design, but then identifying a physical placement layout of transistors-that meets device specifications-is challenging because of the millions or more different layouts possible, each with respective advantages and disadvantages.

### SUMMARY OF THE INVENTION

Maintaining continuous, accurate, and precise operation of semiconductor manufacturing tools is essential for maximizing device yield. These tools, however, often require extensive processing time due to the rigorous calculations needed to ensure devices are manufactured correctly. These calculations provide important feedback for refining initial device designs. Delays and yield losses can significantly decrease productivity and increase the depreciation costs of processing tools. Furthermore, these tools can impact the productivity of engineers and limit opportunities for optimizing designs.

Conventional tools that perform parasitic extraction (PEX) calculations take an initial layout as input, actuate the process to create the complete semiconductor device, and then calculate the resistance and capacitance values based on the process and design. These calculations are then analyzed to correct the layout. This iterative process continues until the desired value set is achieved. This iterative process is very time consuming, which can add significant costs and/or delays to circuit design.

Techniques herein provide methods and systems to improve electronic design accuracy and time. Techniques herein include methods of placing transistors in a physical design to best meet design specifications by using a network trained to extract the capacitance and resistance values of the layout. Networks used herein can include graph neural networks, recurrent neural nets, transformer-like architectures, and optionally incorporate other technologies such as machine learning models for estimating parasitic capacitance and other design values.

A system of one or more computers can be configured to perform particular operations or actions by virtue of having software, firmware, hardware, or a combination of them installed on the system that in operation causes the system to perform the actions. Also, one or more computer programs can be configured to perform particular operations or actions by virtue of including instructions that, when executed by data processing apparatus, cause the apparatus to perform the actions. One general aspect includes a method for automating semiconductor design. This method includes receiving a netlist of an integrated circuit from an electronic design automation tool. The netlist includes a description of electronic components and connectivity including transistors. The method includes identifying transistors from the netlist as nodes for representation in a network. The method also includes creating, by a processing device, a graph neural network that connects nodes from the netlist, with each node in the graph neural network representing a transistor from the netlist. The method includes generating node embeddings for the graph neural network of connected nodes. The method also includes ordering the node embeddings using the graph neural network and performing parasitic extraction between given nodes using the graph neural network to generate parasitic extraction values. The method includes generating a placement order of the transistors for physical layout. The placement order is based on a physical layout design meeting specified design parameter values of a performance metric and a power metric. The method outputs or returns the placement order to a memory store. Other embodiments of this aspect include corresponding computer systems, apparatus, and computer programs recorded on one or more computer storage devices, each configured to perform the actions of the methods.

### BRIEF DESCRIPTION OF DRAWINGS

This disclosure will be understood more fully from the detailed description below and from the accompanying figures of embodiments of the disclosure. The figures are used to facilitate understanding of embodiments of the disclosure and do not limit the scope of the disclosure to these specific embodiments. The figures are not necessarily drawn to scale.

FIG. 1 is a schematic and flow diagram of systems herein for efficient parasitic extraction and training.

FIG. 2 shows a system architecture for embodiments used herein.

FIG. 3 is a diagram of example subsystems used herein.

FIG. 4 is a flow diagram for transistor order placement using a graph neural network.

FIG. 5 is a flow chart of example embodiments herein.

FIG. 6 depicts a representative diagram of an example computer system in which embodiments of the present disclosure may operate.

### DETAILED DESCRIPTION

Techniques herein include methods of placing transistors in a physical design to best meet design specifications by using a network trained to extract the capacitance and resistance values of the layout. Networks used herein can include graph neural networks, recurrent neural nets, and transformers. A related disclosure of inventors includes a machine learning model to appropriate these calculations and process the calculations within seconds using inference-based estimation techniques. This is a localization and weighting model. These machine learning models can provide more than 99% accuracy, and with a latency of seconds to get PPAC values for evaluation.

The localization and weighting model can use these calculations to construct another deep learning model configured to output an acceptable layout with the transistors taken as an input. The output of the model is a correct order of the transistors that can be placed in a sequence to produce a particular semiconductor device, or rather, an order meeting design specifications and that is optimized for performance and/or other metrics. This approach treats each transistor as a word, as in language (speech/text/language), and creates embeddings for each transistor represented as “text.” This transistor set contains the nets of source/gate/drain respectively passed through the network and creates a graph neural network with recursive improvement in the structure. The result from the architecture herein returns a correct order (optimized order or functional order meeting performance metrics) of these transistors that produces a layout with desired PPAC.

More specifically, techniques herein include creating embeddings or embedded values using a recurrent graph neural network (GNN) and then passing the embeddings through a transformer-like architecture to obtain the correct ordering of these embeddings. Data to train the recurrent GNN model is based on a model for localized weighting and federated learning. Such a model is described in U.S. patent application Ser. No. 19/376,681 titled Method and System for Estimating Parasitic Capacitance Using Localized Weighting and Federated Learning Model, filed concurrently herewith, the contents of which are incorporated herein by reference in their entirety. The methods described in the localized weighting model provide efficiency in estimating parasitics by excluding some physical nodes from calculation (limiting nodes included for calculation) and spatially weighting physical nodes used in calculations to estimate parasitic capacitance of various layouts.

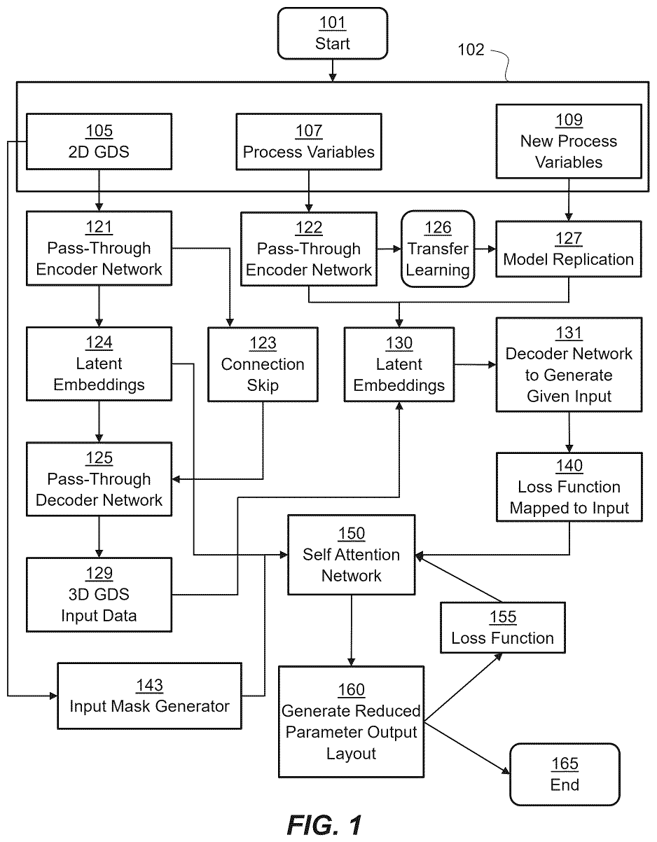

Referring now to FIG. 1, a schematic system diagram and process flow illustrates how various embodiments herein can be combined for improved efficiency in estimating parasitic capacitance in semiconductor device layouts. At step 101, the process starts and initiates a sequence for estimating parasitic capacitance using a neural network-based model that may include federated learning. Inputs 102 serve as the foundational entry point for the system and include three primary data sources: (1) the 2D GDS layout data 105, (2) the process variables 107, and (3) the new process variables 109.

The 2D GDS Input 105 provides a two-dimensional representation of the semiconductor layout. This 2D GDS (Graphic Data System) input can include polygon shapes, layer assignments, feature sizes, spacings, and metal widths. This geometric data is parsed into an internal representation such as a planar graph with nodes representing conductor edges or via endpoints for subsequent feature extraction and encoding. The process variables 107 define the operating conditions and fabrication parameters of the semiconductor device, including layer dielectric constants, ambient temperature, supply voltage, feature size scaling, metal resistivity, doping concentration, oxide thickness, and interlayer capacitance multipliers. These variables directly influence the electromagnetic behavior of the layout and are beneficial to accurate capacitance prediction. The new process variables 109 introduce dynamic parameters that may emerge during model usage or retraining, such as process drift, changes in fabrication recipes, variations in ambient conditions, or user-specified constraints. These are incorporated into the system via input streams or metadata, enabling the model to adapt to evolving process conditions and maintain predictive accuracy.

The pass-through encoder network 121 processes the 2D GDS input 105, transforming the raw geometric/layout data into a latent space representation. In one embodiment, this encoder is a graph neural network (GNN) that takes nodes (e.g. polygon edge, via, metal segment) and edges (adjacency, proximity, nets) and computes node embeddings using several layers (e.g., 35 message passing rounds), with non-linear activations (Rectified Linear Unit, Leaky Rectified Linear Unit) and batch normalization. The network may embed both geometric features (length, width, density) and context features (nearness to other nets, dielectric layer above/below, etc.). Similarly, the pass-through encoder network 122 processes the process variables 107 (and new process variables 109), mapping them to a latent vector or embedding via a fully connected (dense) neural network (multi-layer perceptron), normalizing input variables, optionally applying embedding layers for categorical variables (e.g., material type), and combining into a fixed-size vector. The connection skip 123 provides skip connections from earlier layers of encoders (or between corresponding encoder/decoder stages), enabling bypass of some layers to allow residual paths, reduce vanishing gradient problems, and help preserve fine structural detail from the layout. For example, the encoder's first and/or second layers may be directly connected to corresponding decoder layers.

The latent embedding 124 is the result of combining the outputs of the layout encoder (pass-through encoder network 121) and process variables encoder (pass-through encoder network 122), for example, via concatenation or elementwise addition, optionally followed by projection (dense layers) and optional normalization. This embedding captures the joint influence of geometry, material properties, and layout context in a compact numerical form (e.g. a vector of dimension 128-1024 depending on a given embodiment). The pass-through decoder network 125 reconstructs from the latent embedding 124 an internal representation that is aligned with the input layout specification for purposes such as predicting parasitic capacitances or producing intermediate layout predictions. This decoder may mirror the encoder architecture (e.g., reverse message passing, graph un-pooling) and then map back to per node or per edge values: e.g., predicted capacitance between node pairs, or mapping back to GDS shapes or layout features.

The transfer learning module 126 allows the model trained on one or more Process Design Kits (PDKs), which include design rules, device models, and process parameters that define the foundry's manufacturing capabilities to be adapted to new PDKs. In one embodiment, the model's encoder/decoder weights are pretrained on a large dataset of layouts and process variables from multiple foundries, then fine-tuned on a smaller dataset for the target PDK. In some embodiments, input can include process rules that define a foundry process capability. Hyperparameters (for example, learning rates and regularization) are chosen to avoid overfitting. The model replication 127 component duplicates the trained/fine-tuned model, allowing parallel or distributed inference or evaluation over multiple layout instances or multiple process variable sets. For example, once the model is trained, multiple replicas can run inference on different candidate layouts simultaneously to speed up design evaluation.

The 3D GDS input data 129 provides an optional but more detailed input form: three dimensional layout data including height/thickness of layers, via stacks, interlayer dielectrics, volumetric features. Such 3D input may come from 3D layout tools or be inferred from stacking of 2D layers plus material thickness. This latent embedding 130 captures features of the 3D GDS input data 129, this 3D data is processed to yield latent embeddings 130 by a 3D encoder network (e.g., a volumetric graph or tensor network) that captures interlayer coupling, parasitic effects in the vertical direction, and thus improves accuracy of predicted capacitances (especially coupling capacitance between layers).

The decoder network 131 reconstructs the latent embedding 130 (from the 3D encoder) into predicted layout or capacitance outputs aligned with the original 3D specification: e.g., node to node capacitance, interlayer coupling values, or predicted parasitic values for 3D features. The input mask generator 143 reduces dimensionality by selecting a subset of nodes/features or edges considered for detailed estimation. For example, selections can include masking out features below some width threshold, or far from nets of interest, or selecting high impact nets based on distance, adjacency, or previous estimates. Masking may also be based on a learned criterion (attention scores, or a small network that predicts node importance). This helps reduce computational cost without sacrificing much accuracy.

The loss function 140 evaluates the accuracy of the model's predictions compared to rigorous TCAD (Technology Computer-Aided Design) simulation parasitic extraction (PEX) or simulation data. Loss terms may include mean squared error (MSE) of capacitance values per node pair, percent error, or other domain specific error metrics. Regularization terms (L2 weight decay, possible edge connectivity penalties) may be included. The “mapped to input” phrasing refers to mapping predicted values back to the same layout or nodes used in input so that error is computed over corresponding elements.

The self-attention network 150 identifies relationships or interactions among features. For example, the self-attention network 150 can allow each node in the latent graph embedding to attend to neighboring nodes, nets, or material layers to modulate how much influence each neighbor has on local parasitic behavior. In one embodiment, this is implemented similarly to transformer style attention over graph nodes, or over spatial patches of layout, where attention weights are learned. The loss function 155 further refines the model's predictions by applying auxiliary or combined objectives, for example consistency loss across multiple PDKs, smoothness of capacitance across spatial transitions, or penalty for embedding divergence. Together, loss function 140 and loss function 155 ensure both raw prediction accuracy and generalization.

Step 160 generates an output layout having reduced parameters. That is, from the decoder outputs (whether from 2D only, 3D, or combined), the method produces a layout (or layout metadata) that retains or highlights only parameters or features considered most relevant to parasitic performance. For example, output can be constrained to a fixed percentage (for example, the top 10% to 20%) of nets or node pairs with highest predicted parasitic capacitance, or only features within a threshold distance to critical nets, or limiting outputs to nodes/features above a certain size or width. This reduced parameter layout may omit or suppress less important features in downstream PEX or design checks to speed up design iterations. At step 165, the process ends. This process may be repeated in cycles (retraining, new data) for further refinement, or invoked for each new layout or new process variable set.

Embodiments herein can include a data generation model for transistor embeddings. The data generation model disclosed herein includes several process steps. One step is node generation. Nodes generated represent center points of transistors (for example the centroid of source, gate, drain geometry), and can include corresponding resistance, capacitance (RC) values between any two transistors (e.g., the coupling capacitance or RC delay) derived from known physical extraction tools or simulations. Another step is PEX data inversion. Training data can be obtained by performing inverse calculations on parasitic extraction (PEX) data (from EDA tools) to produce features that best explain observed parasitics, such as solving for unknown adjacency capacitance contributions, or back calculating layout densities. Another step is netlist variations. Such a data generation process includes training on the same set of netlists, but with various placement orders (changing order in which transistors are placed, or variations in physical layout) to learn sensitivity of latent embeddings to layout ordering, adjacency, and density. Note that the input mask to obtain nodes at center point of each transistor can be an input mask for transistors or other filter (for example filtering based on transistor size, or only high-drive transistors).

The data generation model further includes labeling of training samples with corresponding PPAC metrics (Performance, Power, Area, Cost). For each training layout (or netlist+placement+process-variable combination), these PPAC values are computed (or extracted via simulation or via known models). These PPAC metrics are associated with the training instance so that the model can learn to predict or optimize for them.

One embodiment herein uses the generated data to train a recurrent GNN (Graph Neural Network), which creates node embeddings based on the input mask data. The recurrent GNN forms nodes and edges (edges may include adjacency, net connectivity, mutual capacitance potential), and train via backpropagation using the losses defined (loss function 140, loss function 155), to obtain the node embeddings. For example, recurrent GNN can include that node embeddings are updated iteratively. And then in each iteration, messages passed among neighbors and embeddings updated, for example over 3-10 rounds, until convergence or a fixed number of steps.

To achieve a model that processes the netlist as input and determines the optimal order of transistor placement (or ordering), there are process steps that can be executed. One step is designing embeddings. Embeddings are designed for each transistor device, where each transistor described by its source, gate, and drain terminals, is treated as a single embedding vector. Features in that embedding vector may include transistor geometrical parameters (width, length, channel area), electrical parameters (gate oxide thickness, threshold voltage), netlist connectivity (which nets it's connected to, fan in/fan out), proximity to other transistors, et cetera. Each transistor device embedding can be processed through a recurrent (or recursive) neural network (or the GNN) to obtain modified embeddings reflecting layout effects.

In the embodiment involving transformer training, the modified embeddings (from recurrent GNN) are passed through a transformer architecture (multi headed attention, positional encodings corresponding to netlist order or spatial location) to produce a predicted ordering of transistors or features. The transformer may have a stack of layers (for example 412 transformer encoder layers), each consisting of self-attention followed by feedforward layers, layer normalizations, and dropout for regularization. The transformer is trained to minimize a loss between predicted ordering and a rigorous simulation's best transistor placement order (from PPAC ranking). The training dataset includes many netlist/layout/order combinations so that model generalizes.

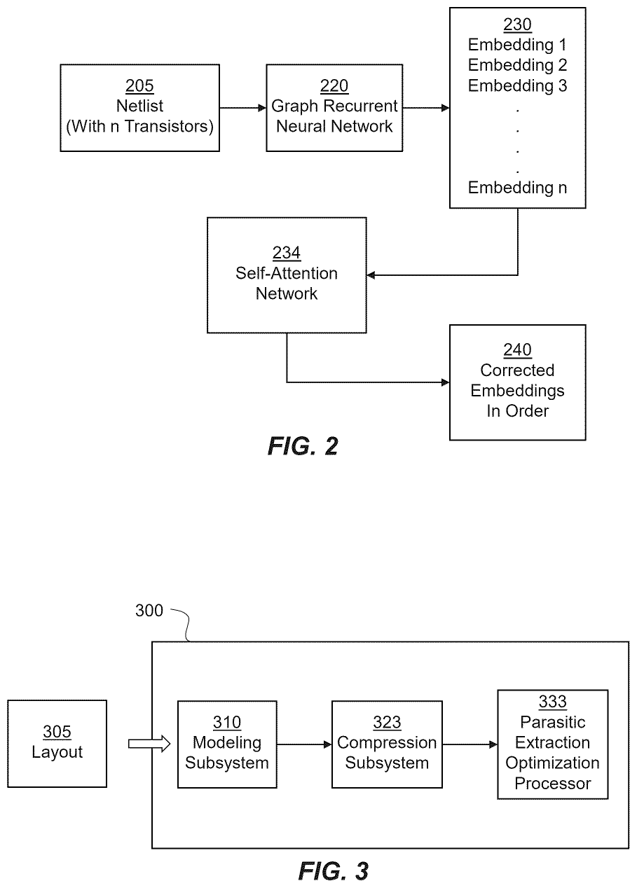

This process ensures that the model accurately determines a placement of transistors closest to specified PPAC values. FIG. 2 illustrates a system architecture of example embodiments herein.

FIG. 2 shows a system architecture for transistor order placement using a graph neural network and self-attention network. A netlist 205, which includes a set of transistors or description of a number of transistors, serves as input to the system. The netlist 205 is processed by a graph recurrent neural network 220. The graph recurrent neural network 220 generates embeddings 230 for each transistor in the netlist 205. These embeddings 230 represent the transistors in a high-dimensional space, capturing their characteristics and relationships.

The embeddings 230 are then passed to a self-attention network 234. The self-attention network 234 processes the embeddings 230 to determine relative importance of each embedding as well as relationships between nodes or embeddings. This network processes the embeddings 230 to produce corrected embeddings 240, which are improved embeddings. The corrected embeddings 240 are ordered in a sequence that optimizes the placement of the transistors. This ordered set of corrected embeddings 240 is the output of the system, providing a placement order that meets specified design parameters for performance, power, area, and cost (PPAC).

FIG. 3 is a simplified schematic showing embodiments using a subsystem 300 or other subsystem of a larger system. The compression subsystem 323—and associated processors—can be an improved computing system and/or algorithm that operates faster compared to conventional parasitic extraction systems, in part because less work is performed by the parasitic capacitance optimization processor 333. The compression subsystem 323 receives input from modeling subsystem 310, which models candidate physical layouts or logical layouts such as received as layout 305.

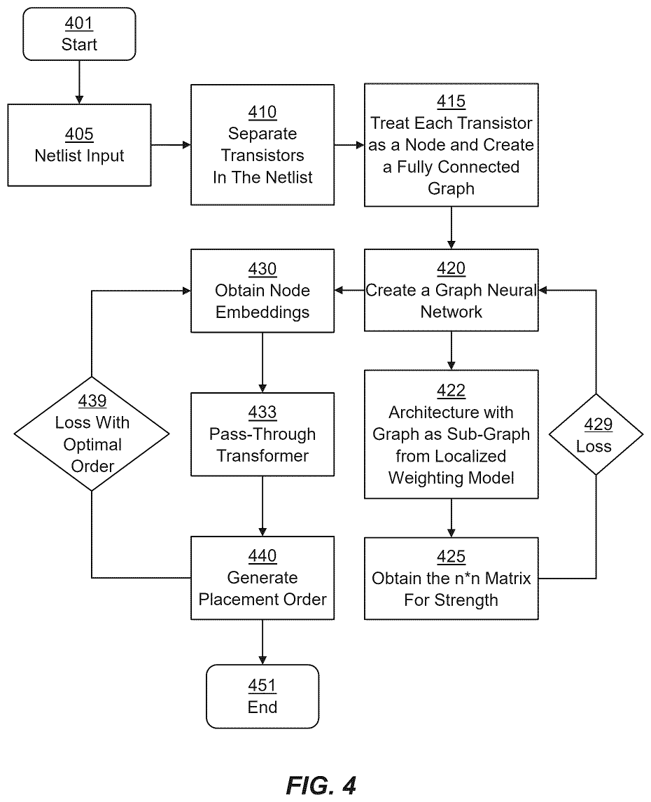

FIG. 4 shows a flow diagram illustrating the process of using a Graph Neural Network (GNN) recursive model to estimate a score or ranking of transistor placement for parasitic extraction and training. Step 401 initiates the process. In step 405 a netlist or other logical design of a circuit is used as input into a system to generate physical designs. The netlist input includes a description of the electronic components and their connectivity, which can include transistors.

In Step 410, the cells in the netlist are separated. This step involves identifying and isolating individual transistors from the netlist to facilitate further processing. Step 415 treats each transistor as a node and creates a fully connected graph. This step involves representing each transistor as a node in a graph, so that all nodes are interconnected to form a comprehensive graph structure.

Step 420 includes creating a graph neural network. The GNN is constructed using the fully connected graph from the previous step, enabling the network to process and analyze the relationships between the nodes (transistors). In Step 422, the architecture can use the graph as a sub-graph or filter for a localized weighting model. This step incorporates a localized weighting to reduce the graph structure, thereby increasing efficiency by masking or filtering the graph to focus on a reduced portion thereof.

Step 425 obtains a given matrix size for strength. This matrix represents the strength of the connections between the nodes, providing a quantitative measure of the relationships within the graph. Step 429 evaluates the loss, or is a loss function element calculating the loss to assess the accuracy and performance of the GNN model. If the loss is not within acceptable limits, the process may iterate to refine the model, which can include creating a new graph neural network or a modified graph neural network.

Step 430 obtains node embeddings. The node embeddings represent the transistors in a high-dimensional space, capturing their characteristics and relationships within the graph. Step 433 passes the node embeddings through a transformer. The transformer processes the embeddings to determine the relative importance and relationships between the nodes, refining the embeddings to produce corrected embeddings.

Step 440 generates the placement order using an edge weight-based graph node traversal to optimize placement order for the transistors, ensuring that the physical layout meets specified or desired design parameters for performance, power, area, and cost (PPAC). This is an improved placement order. For example, the system can begin with an edge and then look for a higher weighting edge and then traverse an entire graph in this manner, looking at lower-level nodes and edge weights, to obtain a placement order. Nodes can be connected with edges and nodes with higher scores can be placed adjacent.

Step 439 evaluates the loss with the optimal order. This step involves calculating the loss function again, but this time with the optimal order of the transistors. This evaluation helps in determining the effectiveness of the placement order generated by the model. Placement orders can be iterated accordingly to further improve the placement order.

Step 451 marks the end of the process or subject process flow herein. The optimized placement order is finalized and can be used for further stages of the semiconductor design and manufacturing process. This can include more rigorous parasitic extraction and evaluation, as well as inspection.

Accordingly, embodiments herein include integration of recurrent graph neural networks (GNNs) with transformer-like architecture to order embeddings and optimize the netlist based on PPAC values. Such a novel data generation approach herein can include using inverse calculations on Parasitic Extraction (PEX) data and training on netlists with various placement orders. Node generation can be based on treating the center points of transistors as nodes and capturing resistance and capacitance values between any two transistors. Optimization is based on PPAC specifications and ranking mechanisms to determine the best netlist order, minimizing PPAC values.

Techniques herein enable quickly identifying a best transistor placement order, minimizing PPAC values (or maximizing depending on design specifications), as ground truth for training the transformer architecture. Techniques include a comprehensive embedding design for transistors, treating each transistor's source, gate, and drain attributes as a single embedding. Techniques also include training the recurrent GNN on generated input mask data to form nodes and connected edges, improving the accuracy of node embeddings.

Techniques herein can be implemented and stored on computer systems including corresponding data storage devices (tangible and non-transitory) for storing instructions, memory for handling instructions, one or more processors for executing instructions, and various inputs, interfaces, and sub-processing units for graphics, audio, and video, as well as signal generation and network connectivity. Techniques herein can include subsystems and subroutines for improved computing compared to conventional systems for electronic design automation.

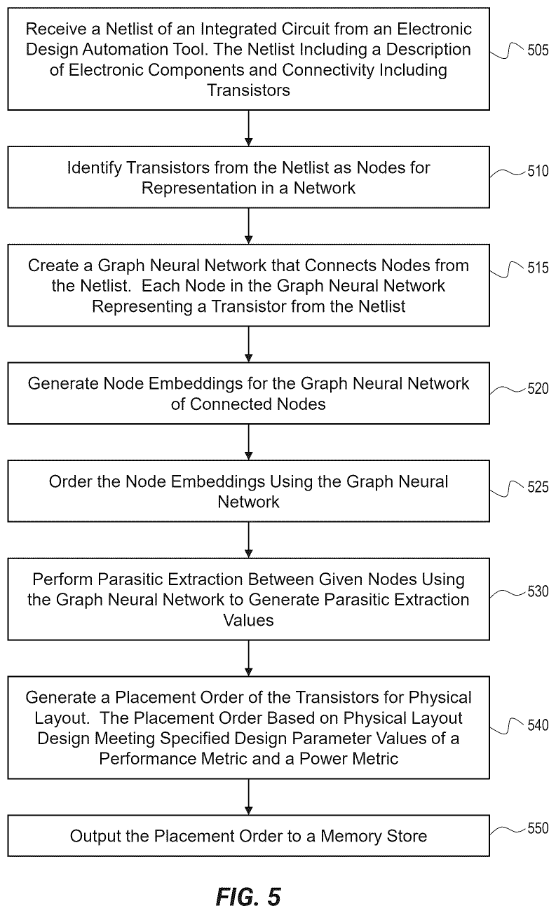

Referring now to FIG. 5, a flow chart illustrates one example embodiment herein. This includes a method and system for automating semiconductor design. In step 505, the system receives a netlist of an integrated circuit from an electronic design automation tool. The netlist can be a netlist, Graphic Design System file such as GDSII, or other similar specification of a circuit design. The electronic design automation tool can include any software product or system for design and evaluation of integrated circuits, though typically for the netlist, for which an acceptable physical design needs to be created. The netlist includes a description of electronic components and connectivity including transistors.

In step 510 the system identifies transistors from the netlist as nodes for representation in a network. In some embodiments, identifying transistors from the netlist as nodes includes modeling the transistors as nodes having a center point of each transistor being a location of respective nodes in a physical design that is used when performing parasitic extraction between given nodes. One tradeoff with such a representation is that parasitic extraction calculation will be somewhat less precise, but the benefit is being able to accelerate and optimize physical design creation by using a graph neural network. This technique can enable quickly identifying a relatively small pool of candidate physical layouts for further evaluation. In other words, a highly efficient method to automatically generate a placement order that satisfies or exceeds design criteria.

In step 515 the system creates a graph neural network that connects nodes from the netlist. Each node in the graph neural network represents a transistor from the netlist. This enables design automation by leveraging networks and relationship identifiers that would otherwise not be available. The graph neural network can be a recurrent graph neural network having a transformer architecture. This can be an architecture that converts nodes into tokens, or be used for ordering the node embeddings.

In step 520 the system generates node embeddings for the graph neural network of connected nodes. Generating the node embeddings can include modeling source, drain, and gate attributes of each transistor as a single embedding.

In step 525 the system orders the node embeddings using the graph neural network. This can include generating multiple placement orders for the netlist and ranking the placement orders based on the performance metric and the power metric. Accordingly, power, performance, area, and cost can be optimized to determine a best order, or an order closest to specified performance values desired. The recurrent graph neural network can also be used to generate the placement order meeting the specified design parameter values of the performance metric and the power metric. In other embodiments, the transformer architecture can be trained by using a top-ranked placement order(s) as ground truth for training the transformer architecture.

In step 530, the system performs parasitic extraction between given nodes using the graph neural network to generate parasitic extraction values.

In step 540, the system generates a placement order of the transistors for physical layout. The placement order can be based on physical layout design meeting specified design parameter values of a performance metric and a power metric. In step 550, the system can output the placement order to a memory store.

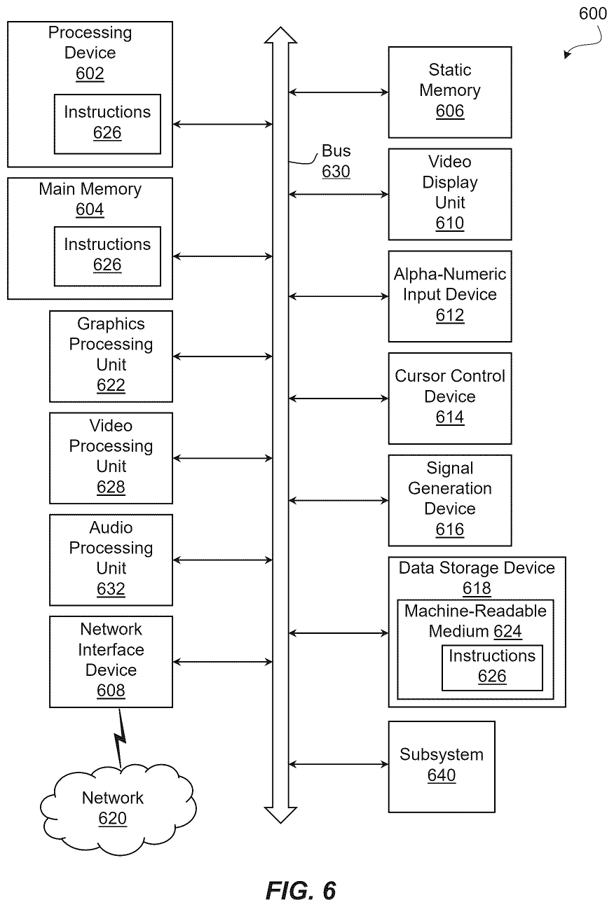

In other embodiments, the system can include receiving the netlist as an input of a modeling subsystem coupled to the electronic design automation tool. And then identifying transistors from the netlist, creating the graph neural network, generating the node embeddings, and ordering the node embeddings can all be executed by a compression subsystem that includes one or more processors. A parasitic capacitance optimization processor coupled to the compression subsystem can be used to perform parasitic extraction and generation of the placement order. These subsystems can be incorporated into Subsystem 640 of FIG. 6.

FIG. 6 depicts a representative diagram of an example computer system in which embodiments of the present disclosure may operate.

A storage subsystem of a computer system (such as computer system 600 of FIG. 6) may be used to store the programs and data structures that are used by some or all of the EDA products described herein, and products used for development of cells for the library and for physical and netlist that use the library.

FIG. 6 illustrates an example machine of a computer system 600 within which a set of instructions, for causing the machine to perform any one or more of the methodologies discussed herein, [including specific technique of this application in electronic design of an integrated circuit], may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The computer system 600 example includes a processing device 602, a main memory 604 (e.g., read-only memory (ROM), flash memory, dynamic random access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed description have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be noted, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

1. A method for automating semiconductor design, the method comprising:
receiving a netlist of a very large-scale integration (VLSI) integrated circuit from an electronic design automation tool, the netlist including a description of electronic components and connectivity including transistors;
identifying transistors from the logical design as nodes for representation in a network;
creating, by a processing device, a graph neural network that connects nodes from the netlist, each node in the graph neural network representing a transistor from the netlist;
generating, by the processing device, node embeddings for the graph neural network of connected nodes;
ordering, by the processing device, the node embeddings using the graph neural network;
performing parasitic extraction, by the processing device, between given nodes using the graph neural network to generate parasitic extraction values;
generating, by the processing device, a placement order of the transistors for physical layout, the placement order based on physical layout design meeting specified design parameter values of a performance metric and a power metric; and
outputting, by the processing device, the placement order to a memory store.

2. The method of claim 1, wherein the graph neural network is a recurrent graph neural network having a transformer architecture used for ordering the node embeddings, the recurrent graph neural network also being used to generate the placement order meeting the specified design parameter values of the performance metric and the power metric.

3. The method of claim 2, wherein identifying transistors from the netlist as nodes includes modeling the transistors as nodes having a center point of each transistor being a location of respective nodes in a physical design that is used when performing parasitic extraction between given nodes.

4. The method of claim 3, further comprising:
generating, by the processing device, multiple placement orders for the netlist and ranking the placement orders based on the performance metric and the power metric.

5. The method of claim 4, further comprising:
training the transformer architecture by using a top-ranked placement order as ground truth for training the transformer architecture.

6. The method of claim 1, wherein receiving the netlist includes using an input of a modeling subsystem coupled to the electronic design automation tool;
wherein identifying transistors from the netlist, creating the graph neural network, generating the node embeddings, and ordering the node embeddings are executed by a compression subsystem that includes one or more processors; and
wherein performing the parasitic extraction and generating the placement order are executed by a parasitic capacitance optimization processor coupled to the compression subsystem.

7. The method of claim 6, wherein generating the node embeddings includes modeling source, drain, and gate attributes of each transistor as a single embedding.

8. A system comprising:
a memory storing instructions; and
a processor, coupled with the memory and configured to execute the instructions, the instructions when executed cause the processor to:
receive a netlist of an integrated circuit from an electronic design automation tool, the netlist including a description of electronic components and connectivity including transistors;
identify transistors from the netlist as nodes for representation in a network;
create a graph neural network that connects nodes from the netlist, each node in the graph neural network representing a transistor from the netlist;
generate node embeddings for the graph neural network of connected nodes;
order the node embeddings using the graph neural network;
perform parasitic extraction between given nodes using the graph neural network to generate parasitic extraction values;
generate a placement order of the transistors for physical layout, the placement order based on physical layout design meeting specified design parameter values of a performance metric and a power metric; and
output the placement order to a memory store.

9. The system of claim 8, wherein the graph neural network is a recurrent graph neural network having a transformer architecture used for ordering the node embeddings, the recurrent graph neural network also being used to generate the placement order meeting the specified design parameter values of the performance metric and the power metric.

10. The system of claim 9, wherein the instruction to identify transistors from the netlist as nodes includes instruction to model the transistors as nodes having a center point of each transistor being a location of respective nodes in a physical design that is used when performing parasitic extraction between given nodes.

11. The system of claim 10, wherein the instructions further cause the processor to:
generate multiple placement orders for the netlist and rank the placement orders based on the performance metric and the power metric.

12. The system of claim 11, wherein the instructions further cause the processor to:
train the transformer architecture by using a top-ranked placement order as ground truth for training the transformer architecture.

13. The system of claim 12, wherein the instruction to generate the node embeddings includes instruction to model source, drain, and gate attributes of each transistor as a single embedding.

14. The system of claim 13, wherein the instruction to receive the netlist includes instruction to use an input of a modeling subsystem coupled to the electronic design automation tool;
wherein the instructions to identify transistors from the netlist, create the graph neural network, generate the node embeddings, and order the node embeddings include instruction to be executed by a compression subsystem that includes one or more processors; and
wherein the instructions to perform the parasitic extraction and generate the placement order include instructions to be executed by a parasitic capacitance optimization processor coupled to the compression subsystem.

15. A non-transitory computer readable medium comprising stored instructions, which when executed by a processor, cause the processor to:
receive a netlist of an integrated circuit from an electronic design automation tool, the netlist including a description of electronic components and connectivity including transistors;
identify transistors from the netlist as nodes for representation in a network;
create a graph neural network that connects nodes from the netlist, each node in the graph neural network representing a transistor from the netlist;
generate node embeddings for the graph neural network of connected nodes;
order the node embeddings using the graph neural network;
perform parasitic extraction between given nodes using the graph neural network to generate parasitic extraction values;
generate a placement order of the transistors for physical layout, the placement order based on physical layout design meeting specified design parameter values of a performance metric and a power metric; and
output the placement order to a memory store.

16. The non-transitory computer readable medium of claim 15, wherein the graph neural network is a recurrent graph neural network having a transformer architecture used for ordering the node embeddings, the recurrent graph neural network also being used to generate the placement order meeting the specified design parameter values of the performance metric and the power metric.

17. The non-transitory computer readable medium of claim 16, wherein the instruction to identify transistors from the netlist as nodes includes instruction to model the transistors as nodes having a center point of each transistor being a location of respective nodes in a physical design that is used when performing parasitic extraction between given nodes.

18. The non-transitory computer readable medium of claim 17, wherein the instructions further cause the processor to:
generate multiple placement orders for the netlist and rank the placement orders based on the performance metric and the power metric; and
train the transformer architecture by using a top-ranked placement order as ground truth for training the transformer architecture.

19. The non-transitory computer readable medium of claim 15, wherein the instruction to generate the node embeddings includes instruction to model source, drain, and gate attributes of each transistor as a single embedding.

20. The non-transitory computer readable medium of claim 15, wherein the instruction to receive the netlist includes instruction to use an input of a modeling subsystem coupled to the electronic design automation tool;
wherein the instructions to identify transistors from the netlist, create the graph neural network, generate the node embeddings, and order the node embeddings include instruction to be executed by a compression subsystem that includes one or more processors; and
wherein the instructions to perform the parasitic extraction and generate the placement order include instructions to be executed by a parasitic capacitance optimization processor coupled to the compression subsystem.
